(19) United States
(12) Patent Application Publication
(10) Pub. No.: US 2007/0012977 A1
(43) Pub. Date: Jan. 18, 2007

(54) Semiconductor device and method for forming the same

(76) Inventors: Tai-Bor Wu, Hsinchu (TW); Chun-Kai Huang, Hsinchu (TW)

Correspondence Address: LADAS & PARRY LLP, 224 SOUTH MICHIGAN AVENUE, SUITE 1600, CHICAGO, IL, 60604, US

(21) Appl. No.: 11/522,593

(22) Filed: Sep. 18, 2006

Related U.S. Application Data
(63) Continuation-in-part of application No. 11/103,322, filed on Apr. 11, 2005.

(51) Int. Cl. H01L 29/94; H01L 21/00

(52) U.S. Cl. 257/295; 257/532; 438/957; 257/535; 438/3; 257/E27.104

(57) ABSTRACT

A semiconductor device includes a MOS transistor having a capacitor-forming surface; and a ferroelectric capacitor formed on the capacitor-forming surface of the MOS transistor and including upper and lower electrode layers of Pt and a dielectric layer sandwiched between the upper and lower electrode layers. The ferroelectric capacitor has a cross-section that is generally trapezoid in shape, and that has an inclined side which forms an angle of greater than 45 degrees and less than 90 degrees with the capacitor-forming surface of the MOS transistor.

### CROSS-REFERENCE TO RELATED APPLICATION

This application is a continuation-in-part (CIP) of U.S. patent application Ser. No. 11/103,322, filed by the applicant on Apr. 11, 2005, and abandoned as of the filing date of this application.

### BACKGROUND OF THE INVENTION

1. Field of the Invention

This invention relates to a semiconductor device and a method for forming the semiconductor device, more particularly to a method involving etching a Pt—PtOₓ layer and subsequently reducing the etched Pt—PtOₓ layer into a Pt layer.

2. Description of the Related Art

FIG. 1 illustrates a conventional semiconductor device that includes a MOS transistor 200 and a ferroelectric capacitor 1 formed on the MOS transistor 200 through semiconductor processing techniques. The ferroelectric capacitor 1 is electrically connected to the MOS transitor 200 through a conductive wire 300. The ferroelectric capacitor 1 includes upper and lower electrode layers 13, 11 and a dielectric layer 12 sandwiched between the upper and lower electrode layers 13, 11. The dielectric layer 12 is made from a ferroelectric material, such as PbZr₁₋ₓTiₓO₃ (PZT), Ba₁₋ₓSrₓTiO₃ (BST), and Ba(Zn₁₋ₓTaₓ)O₃ (BZT). The upper and lower electrode layers 13, 11 are made from a noble metal, such as platinum (Pt), or a metal compound, such as RuO₂, IrO₂, and LaNiO₃.

Since IrO₂ and LaNiO₃ are difficult to be etched, and since RuO₂can produce toxic gas during etching when using chlorine- or fluorine-containing etchant, Pt is usually used as a material for the upper and lower electrode layers 13, 11. However, etching of a Pt electrode to a desired pattern for subsequent wafer dicing is still difficult, and fine pattern of the Pt electrode is very difficult to achieve using current etching techniques. As best illustrated in FIG. 1, due to the difficulty in etching the Pt upper electrode 13, the ferroelectric capacitor 1 is undesirably formed into a pyramid in shape and has an etching slope, indicated as an angle α in FIG. 1, less than 45 degrees, which results in poor performance thereof. In order to have a good performance, the angle α is preferably greater than 75 degrees. In addition, hydrogen degradation of the dielectric layer 12 induced in the hydrogen-gas annealing of the conductive wire 300 occurs due to catalytic characteristics of the Pt electrode (i.e., the upper and lower electrodes 13, 11), which results in formation of hydrogen ions that penetrate through the Pt electrode and into the dielectric layer 12.

U.S. Pat. No. 6,169,305 discloses a semiconductor device that includes a ferro-electric film sandwiched between upper and lower electrodes of a Pt/PtOₓ/IrO₂structure or a Pt/PtOₓ/SRO structure. Formation of the Pt/PtOₓ/IrO₂-based semiconductor device or the Pt/PtOₓ/SRO-based semiconductor device includes the steps of forming a silicon oxide film, forming a lower IrO₂ (or SRO) film on the silicon oxide film, forming a lower PtOₓ film on the lower IrO₂ film, forming a lower Pt film on the lower PtOₓ film, forming a ferro-electric film (PZT film) on the lower Pt film, annealing the layered structure thus formed, forming an upper IrO₂ (or SRO) film on the PZT film, forming an upper PtOₓ film on the upper IrO₂ film, and forming an upper Pt film on the upper PtOₓ film. Then, the assembly of the PZT film, the upper and lower Pt films, the upper and lower PtOₓ films, and the upper and lower IrO₂ films is patterned by photolithography. The upper Pt film, the upper PtOₓ film, and the upper IrO₂ film constitute the upper electrode of Pt/PtOₓ/IrO₂, while the lower Pt film, the lower PtOX film, and the lower IrO₂ film constitute the lower electrode of Pt/PtOₓ/IrO₂. The aforesaid patterning can be conducted using dry etching techniques. An etching condition may be, e.g., Cl₂ and Ar gas as etching gases.

Although the layered structure of each of the upper and lower electrodes of the semiconductor device of the aforesaid U.S. patent includes a PtOₓ film, the presence of the upper and lower Pt films in the layered structure makes the aforesaid dry etching relatively difficult and is likely to result in the same drawbacks encountered in the previous semiconductor device of FIG. 1.

### SUMMARY OF THE INVENTION

The object of the present invention is to provide a method for forming a semiconductor device that is capable of overcoming the aforesaid drawbacks of the prior art.

According to one aspect of this invention, there is provided a semiconductor device that comprises: a MOS transistor having a capacitor-forming surface; and a ferroelectric capacitor formed on the capacitor-forming surface of the MOS transistor and including upper and lower electrode layers of Pt and a dielectric layer sandwiched between the upper and lower electrode layers. The ferroelectric capacitor has a cross-section that is generally trapezoid in shape, and that has an inclined side which forms an angle of greater than 45 degrees and less than 90 degrees with the capacitor-forming surface of the MOS transistor.

According to another aspect of this invention, there is provided a method for forming a ferroelectric capacitor on a MOS transistor of a semiconductor device. The method comprises: forming a lower electrode layer on a capacitor-forming surface of the MOS transistor; forming a dielectric layer on the lower electrode layer; forming an upper electrode layer of a uniformly mixed Pt—PtOₓ material, in which x is an integer from 1 to 2, on the dielectric layer; patterning the assembly of the upper and lower electrode layers and the dielectric layer by photolithography techniques; and reducing PtOₓ of the Pt—PtOₓ material of the upper electrode layer into Pt by annealing the upper electrode layer.

### BRIEF DESCRIPTION OF THE DRAWINGS

Other features and advantages of the present invention will become apparent in the following detailed description of the preferred embodiment of the invention, with reference to the accompanying drawings, in which:

FIG. 1 is a schematic view to illustrate a ferroelectric capacitor of a conventional semiconductor device;

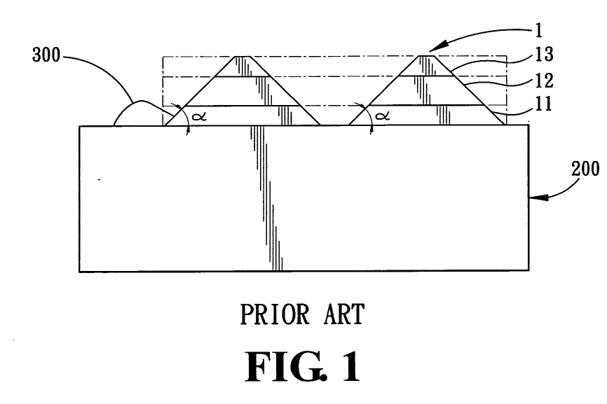

FIG. 2 is a schematic view to illustrate the preferred embodiment of a semiconductor device according to this invention;

FIG. 3 is a graph of etching rate and selectivity for ferroelectric capacitors of the semiconductor device of the preferred embodiment and the conventional semiconductor device;

FIG. 4 is a graph of XPS intensity for the semiconductor device of the preferred embodiment and the conventional semiconductor device; and

FIG. 5 is a graph of polarization versus electric field (P-E hysteresis curves) for the semiconductor device of the preferred embodiment and the conventional semiconductor device.

### DETAILED DESCRIPTION OF THE PREFERRED EMBODIMENT

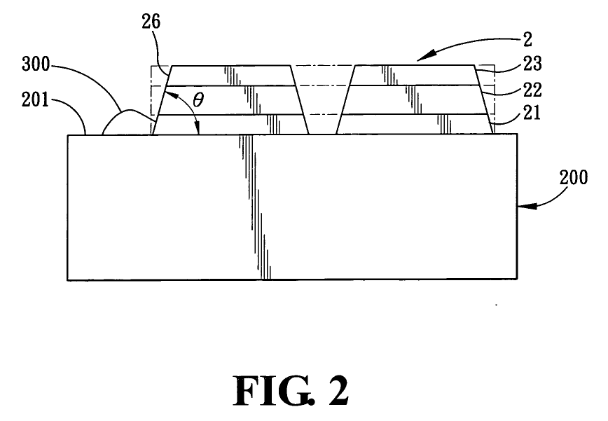

FIG. 2 illustrates the preferred embodiment of a semiconductor device according to this invention.

The semiconductor device includes: a MOS transistor 200 having a capacitor-forming surface 201; a ferroelectric capacitor 2 formed on the capacitor-forming surface 201 of the MOS transistor 200 and including upper and lower electrode layers 23, 21 and a dielectric layer 22 sandwiched between the upper and lower electrode layers 23, 21; and a conductive wire 300 electrically connected to the ferroelectric capacitor 2 and the MOS transistor 200. Each of the upper and lower electrode layers 23, 21 is made from Pt. The ferroelectric capacitor 2 has a cross-section that is generally trapezoid in shape, and that has an inclined side 26 that forms an angle θ of greater than 45 degrees and less than 90 degrees with the capacitor-forming surface 201 of the MOS transistor 200. Preferably, the angle θ is greater than 75 degrees and less than 90 degrees.

The dielectric layer 22 is made from a ferroelectric material selected from the group consisting of PbZr₁₋ₓTiₓO₃ (PZT), Strontium bismuth tantalite (SBT), Ba(Zn₁₋ₓTaₓ)O₃ (BZT), Ba₁₋ₓSrₓTiO₃ (BST), and combinations thereof.

The semiconductor device of this invention can be made by a method including the steps of: forming the lower electrode layer 21 of a uniformly mixed Pt—PtOₓ material, in which x is an integer from 1 to 2, on the capacitor-forming surface 201 of the MOS transistor 200 using deposition techniques, such as physical vapor deposition (PVD), sputtering, chemical vapor deposition (CVD), or Sol-Gel techniques; forming the dielectric layer 22 on the lower electrode layer 21 using the aforesaid deposition techniques or the Sol-Gel techniques; forming the upper electrode layer 23 of the uniformly mixed Pt—PtOₓ material on the dielectric layer 22 using the aforesaid deposition techniques or the Sol-Gel techniques; patterning the assembly of the upper and lower electrode layers 23, 21 and the dielectric layer 22 by photolithography techniques; forming the conductive wire 300 to interconnect electrically the ferroelectric capacitor 2 and the MOS transistor 200; and reducing PtOₓ of the Pt—PtOₓ material of the upper and lower electrode layers 23, 21 into Pt. Preferably, the weight percentage of PtOₓ is in an amount ranging from 50-100% based on the total weight of the Pt—PtO, material.

In this embodiment, formation of the upper and lower electrode layers 23, 21 is performed using sputtering techniques by sputtering a Pt target in a gas mixture of Ar/O₂ such that formation of PtOₓ through reaction of Pt with the oxygen of the gas mixture occurs during deposition of Pt on the capacitor-forming surface 201 of the MOS transistor 200. Preferably, the ratio of Ar to O₂ of the gas mixture ranges from 50:50 to 60:40. The sputtering is conducted at a temperature ranging from 140 to 180° C.

Patterning of the ferroelectric capacitor 2 is preferably conducted by dry etching techniques, such as plasma etching, so as to form the desired cross-section as best shown in FIG. 2. In this embodiment, the assembly of the upper and lower electrode layers 23, 21 and the dielectric layer 22 is etched in the patterning operation using Cl₂/Ar gas mixture. Since, PtOₓ has a much higher etching rate than Pt, an etching slope, represented by the angle θ shown in FIG. 2, over 75 degrees can be obtained for the cross-section of the ferroelectric capacitor 2. The result is an improvement over the conventional semiconductor device with Pt electrodes having an etching slope less than 45 degrees.

After formation of the conductive wire 300, the assembly of the MOS transistor 200, the ferroelectric capacitor 2 and the conductive wire 300 is subjected to hydrogen-gas annealing in a gas mixture of N₂/H₂ at an annealing temperature ranging from 280 to 360° C. for reducing PtOₓ of the upper and lower electrode layers 23, 21 into Pt and for reducing the resistance of the conductive wire 300. Preferably, the concentration of the hydrogen present in the gas mixture is 2 to 5%.

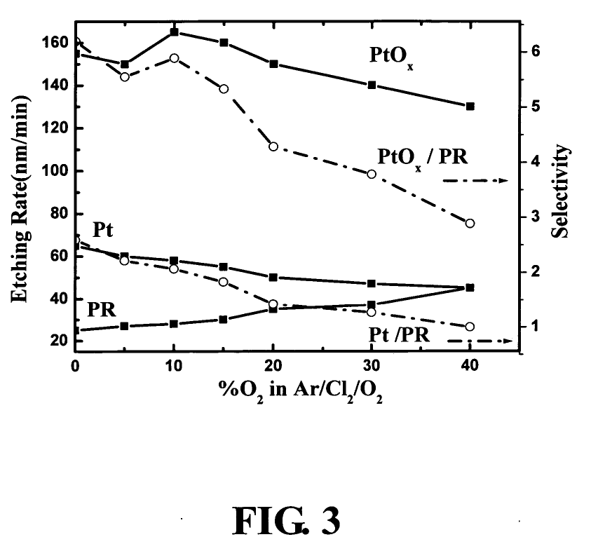

FIG. 3 shows etching rate for a PtOₓ-containing film and a Pt film, as well as their etching selectivity against a photoresist (PR) film, as a function of O₂ content in a Ar/Cl₂/O₂ plasma. The etching test was conducted at a gas pressure of 5 mTorr, a source power of 2100 W, and a bias power of 250 W. The results show that the PtOₓ-containing film has a much higher etching rate and etching selectivity than those of Pt film.

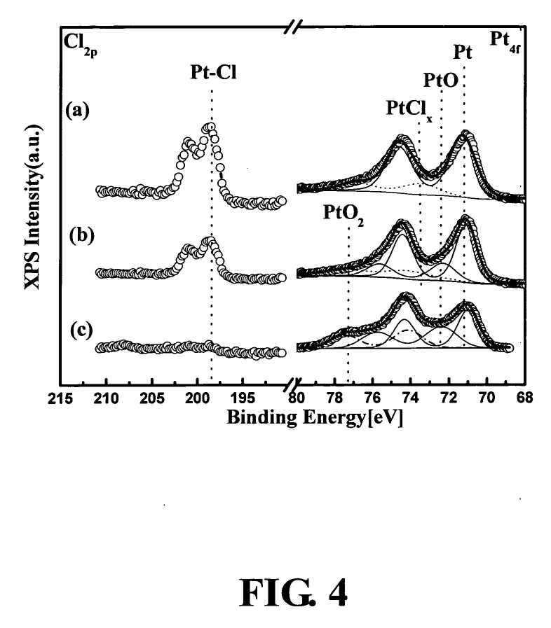

FIG. 4 shows intensity of x-ray photoelectron spectroscopy (XPS) of Cl₂ₚ and Pt_{4f} electrons of the etched PtOₓ-containing film and the PT film. In FIG. 4, (a) represents XPS of Pt film in Ar/Cl₂ (20%) plasma, (b) represents XPS of PtOₓ-containing film in Ar/Cl₂ (20%) plasma, and (c) represents XPS of PtOₓ-containing film in Ar/Cl₂ (20%)/O₂ (50%) plasma. The results show that less PtClₓ redeposited on the PtOₓ-containing film than on the Pt film for etching in the Ar/Cl₂ plasma, and that the redeposition of PtClₓ can be well eliminated by addition of O₂ in the plasma. It is noted that an additional peak corresponding to the PtO₂ phase appears at the binding energy of 77.3 eV for PtOₓ-containing film etched in the Ar/Cl₂ (20%)/O₂ (50%) plasma. The result indicates that the PtOₓ-containing film can be further oxidized by oxygen plasma to form a PtO₂ layer on the etched surface, which, was not observed in the etching of Pt film with oxygen plasma.

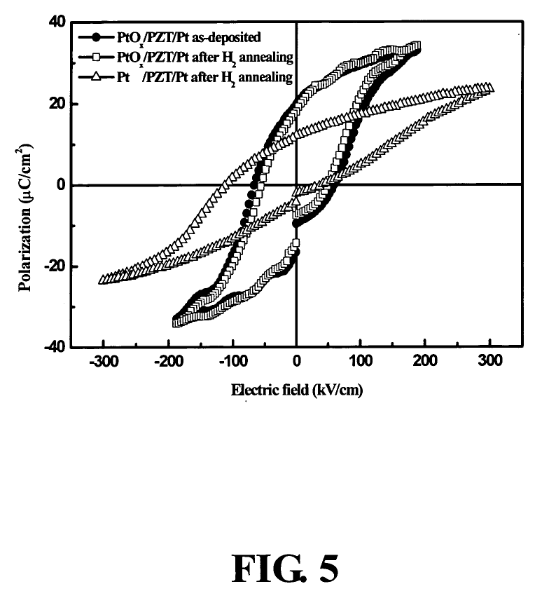

FIG. 5 shows the polarization versus electric field (P-E) hysteresis curves for capacitors with different electrodes (i.e., Pt electrode and PtOₓ electrode). The capacitors include electrodes coated on a PZT film, which were annealed in a H₂ plasma at 300° C. for one minute. The results show that the P-E characteristics of the PtOₓ electrode formed capacitor remains unchanged before and after hydrogen plasma annealing, whereas the Pt electrode formed capacitor degrades significantly. The high degradation resistance reveals the hydrogen blocking ability of the PtOₓ electrode, thereby eliminating the hydrogen degradation of the dielectric layer as encountered in the conventional semiconductor device during hydrogen gas annealing of the conductive wire of the semiconductor device.

By using Pt—PtOₓ for forming the upper and lower electrode layers 23, 21 to facilitate etching of the ferroelectric capacitor 2 of the semiconductor device of this invention in the patterning operation, followed by reducing Pt—PtOₓ into Pt, the aforesaid drawbacks associated with the prior art can be eliminated.

While the present invention has been described in connection with what is considered the most practical and preferred embodiment, it is understood that this invention is not limited to the disclosed embodiment but is intended to cover various arrangements included within the spirit and scope of the broadest interpretations and equivalent arrangements.

We claim:

1. A semiconductor device comprising:
a MOS transistor having a capacitor-forming surface; and
a ferroelectric capacitor formed on said capacitor-forming surface of said MOS transistor and including upper and lower electrode layers of Pt and a dielectric layer sandwiched between said upper and lower electrode layers;
wherein said ferroelectric capacitor has a cross-section that is generally trapezoid in shape and that has an inclined side which forms an angle of greater than 45 degrees and less than 90 degrees with said capacitor-forming surface of said MOS transistor.

2. The semiconductor device of claim 1, wherein said angle is greater than 75 degrees and less than 90 degrees.

3. The semiconductor device of claim 1, wherein said dielectric layer is made from a ferroelectric material selected from the group consisting of PZT, SBT, BZT, BST, and combinations thereof.

4. A method for forming a ferroelectric capacitor on a MOS transistor of a semiconductor device, comprising:
forming a lower electrode layer on a capacitor-forming surface of the MOS transistor;
forming a dielectric layer on the lower electrode layer;
forming an upper electrode layer of a uniformly mixed
Pt—PtOₓ material, in which x is an integer from 1 to 2, on the dielectric layer;
patterning the assembly of the upper and lower electrode layers and the dielectric layer by photolithography techniques; and
reducing PtOₓ of the Pt—PtOₓ material of the upper electrode layer into Pt by annealing the upper electrode layer.

5. The method of claim 4, wherein the weight percentage of PtOₓ is in an amount ranging from 50-100% based on the total weight of the Pt—PtOₓ material.

6. The method of claim 5, wherein each of the upper and lower electrode layers is formed by sputtering a Pt target in a gas mixture of Ar/O₂ such that formation of PtOₓ through reaction of Pt with the oxygen of the gas mixture occurs during deposition of Pt.

7. The method of claim 6, wherein the ratio of Ar to O₂ of the gas mixture ranges from 50:50 to 60:40.

8. The method of claim 6, wherein the sputtering deposition is conducted at a temperature ranging from 140 to 180° C.

9. The method of claim 4, wherein the reducing of PtOₓ into Pt is conducted at an annealing temperature ranging from 280 to 360° C.

10. The method of claim 4, wherein the assembly of the upper and lower electrode layers and the dielectric layer is etched in the patterning operation using Cl₂/Ar gas mixture.

11. The method of claim 10, wherein the assembly of the upper and lower electrode layers and the dielectric layer is etched such that the assembly has a cross-section which is generally trapezoid in shape and which has an inclined side that forms an angle of greater than 45 degrees and less than 90 degrees with the capacitor-forming surface of the MOS transistor.
